(19) United States
(12) Patent Application Publication
(10) Pub. No.: US 2016/0204384 A1
(43) Pub. Date: Jul. 14, 2016

(54) Electroluminescent Element and Lighting Apparatus Including Same

(71) Applicant: Konica Minolta, Inc., Chiyoda-ku, Tokyo (JP)

(72) Inventor: Koujirou SEKINE, Ibaraki-shi, Osaka (JP)

(21) Appl. No.: 14/442,252

(22) PCT Filed: Oct. 23, 2013
(86) PCT No.: PCT/JP2013/078673

§ 371 Date: May 12, 2015

(30) Foreign Application Priority Data
Nov. 14, 2012 (JP) 2012-250383

(51) Int. Cl. H01L 51/52; H01L 51/50

(52) U.S. Cl. CPC H01L 51/5275; H01L 51/5271; H01L 51/5012; H01L 2251/558

(57) ABSTRACT

An organic EL element includes a transparent substrate, a first transparent electrode layer, an organic electroluminescent layer, a second transparent electrode layer, and a reflecting layer. The refractive index of the transparent substrate is lower than the refractive index of any film included in the organic electroluminescent layer. Both the refractive index of the first transparent electrode layer and the refractive index of the second transparent electrode layer are lower than the refractive index of any film included in the organic electroluminescent layer.

### TECHNICAL FIELD

The present invention relates to electroluminescent elements (electroluminescence element, hereinafter also referred to as “EL element”), as represented by organic electroluminescent elements and inorganic electroluminescent elements, and lighting apparatuses including the same.

### BACKGROUND ART

An EL element, as represented by an organic EL element and an inorganic EL element, generally has a configuration in which an electroluminescent layer, a transparent electrode layer, a reflecting layer, and the like are layered on a transparent substrate. A light emitted from the electroluminescent layer is extracted through the transparent electrode layer, so that the light is irradiated outward. Among those, the organic EL element particularly can obtain a high brightness with low power consumption and exhibits a superior performance also in terms of a response, a service life, and the like.

However, the light which can be extracted to outside from the EL element is limited to about 20% of the light emitted from the electroluminescent layer, and the remaining major part is lost. For example, in a bottom emission EL element which extracts a light to outside through a transparent substrate, the loss is classified into a substrate loss, a waveguide loss, and a plasmon loss.

The substrate loss occurs when a light emitted from an electroluminescent layer is coupled to a substrate mode of confining the light in a transparent substrate. The waveguide loss occurs when a light emitted from an electroluminescent layer is coupled to a waveguide mode of confining the light in an electroluminescent layer, a transparent electrode layer, or the like. On the other hand, the plasmon loss occurs when a light emitted from an electroluminescent layer is coupled to a plasmon mode of exciting a surface plasmon of a metal film such as a reflecting layer.

Therefore, EL elements of various configurations have been conventionally proposed so as to allow a light emitted from an electroluminescent layer to be extracted to outside with a higher efficiency.

For example, Japanese Patent Laying-Open No. 2011-222529 (PTD 1) discloses an organic EL element configured such that, when it is provided that the thickness of an organic electroluminescent layer is d, and the refractive index of the organic electroluminescent layer is n, and the wavelength of a light emitted from the organic electroluminescent layer is λ, these items d, n, and λ, satisfy the condition of d≦λ/(4×n) to allow the reduction of the waveguide loss.

Moreover, Japanese Patent Laying-Open No. 2009-181856 (PTD 2) discloses that, in an organic EL element, a transparent electrode layer is constituted of so-called complex conductive film or the like having a wire-like conductive material included in resin so that the refractive index of the transparent electrode layer can be suppressed to be less than or equal to 1.8 which is a lower limit value of the refractive index of ITO (a mixture of indium oxide and tin oxide) as a general material of a transparent electrode layer, thereby reducing the waveguide loss.

### CITATION LIST

### Patent Document

PTD 1: Japanese Patent Laying-Open No. 2011-222529

PTD 2: Japanese Patent Laying-Open No. 2009-181856

### SUMMARY OF INVENTION

### Technical Problem

However, in the configurations disclosed in Japanese Patent Laying-Open No. 2011-222529 and Japanese Patent Laying-Open No. 2009-181856, a considerable reduction of the waveguide loss is expected. However, since the metal film or the like as a reflecting layer is arranged in contact with or close to the electroluminescent layer, the plasmon loss cannot be reduced at all or cannot be reduced sufficiently.

In order to reduce the plasmon loss, it is effective to arrange the electroluminescent layer and the metal film considerably far apart from each other. However, it would be necessary to fill a space between the electroluminescent layer and the metallic film with some kind of a relatively thick transparent member.

In this regard, in the configuration disclosed in Japanese Patent Laying-Open No. 2011-222529, one electrode layer adjacent to the electroluminescent layer is constituted of a metal film which also serves as a reflecting layer. Therefore, since the electroluminescent layer and the metal film primarily cannot be arranged far apart from each other, there is a disadvantage that the occurrence of the plasmon loss cannot be reduced as described above.

Moreover, in the configuration disclosed in Japanese Patent Laying-Open No. 2009-181856, a complex conductive film is used as a transparent electrode layer located on a side of the reflecting layer as described above. Therefore, the refractive index thereof is slightly below 1.8 and is not sufficiently low, and there is a disadvantage that even the reduction of the waveguide loss may also be insufficient in accordance with the thickness of the complex conductive film.

Thus, the present invention was made in view of the problems described above, and its object is to provide an electroluminescent element capable of reducing both the waveguide loss and plasmon loss and extracting a light emitted from an electroluminescent layer to outside with a high efficiency and to provide a lighting apparatus including the same.

### Solution to Problem

An electroluminescent element in accordance with the present invention includes a transparent substrate, a first transparent electrode layer provided on one main surface of the transparent substrate, an electroluminescent layer provided on a main surface of the first transparent electrode layer on a side opposite to the side on which the transparent substrate is located, a second transparent electrode layer provided on a main surface of the electroluminescent layer on a side opposite to the side on which the first transparent electrode layer is located, and a reflecting layer constituted of a metal film and provided on a side opposite to the side on which the electroluminescent layer is located when viewed from the second transparent electrode layer. The effective refractive index of the transparent substrate is lower than the refractive index of any film included in the electroluminescent layer, and both the effective refractive index of the first transparent electrode layer and the effective refractive index of the second transparent electrode layer are lower than the refractive index of any film included in the electroluminescent layer.

When a particular layer is constituted of a single film, the effective refractive index represents the refractive index of the single film. When a particular layer is constituted of a plurality of layers, the effective refractive index represents the effective refractive index which is derived taking into account the respective refractive indices and film thicknesses of the plurality of films. For example, when the layer is constituted of a layered film including a film with a refractive index nA and a film thickness dA and a film with a refractive index nB and a film thickness dB, the effective refractive index of the layer is (nA×dA+nB×dB)/(dA+dB).

A lighting apparatus in accordance with the present invention includes the electroluminescent element of the present invention as a light source.

### Advantageous Effects of Invention

According to the present invention, an electroluminescent element capable of reducing both the waveguide loss and plasmon loss and extracting a light emitted from an electroluminescent layer to outside with a high efficiency, and a lighting apparatus including the same can be provided.

### BRIEF DESCRIPTION OF DRAWINGS

FIG. 1 is a schematic plan view representing an organic EL element in accordance with a first embodiment of the present invention.

FIG. 2 is a schematic cross sectional view representing the organic EL element shown in FIG. 1.

FIG. 3 is a schematic cross sectional view representing an organic EL element in accordance with a second embodiment of the present invention.

FIG. 4 is a schematic cross sectional view representing an organic EL element in accordance with a third embodiment of the present invention.

FIG. 5 is a schematic cross sectional view representing an organic EL element in accordance with a fourth embodiment of the present invention.

FIG. 6 is a schematic view representing a lighting apparatus in accordance with a fifth embodiment of the present invention.

FIG. 7 is a schematic view representing a lighting apparatus in accordance with a sixth embodiment of the present invention.

FIG. 8 is a schematic cross sectional view representing an organic EL element in accordance with Comparative Example 1.

FIG. 9 is a schematic cross sectional view representing an organic EL element in accordance with Comparative Example 2.

FIG. 10 is a graph representing a relationship between the thickness of a high refractive index part of the organic EL element and the equivalent refractive index of the waveguide mode for different wavelengths in accordance with Comparative Example 1.

FIG. 11 is a graph representing a relationship between the thickness of a high refractive index part of the organic EL element and the equivalent refractive index of the waveguide mode for different wavelengths in accordance with Comparative Example 2.

FIG. 12 is a graph representing a relationship between the thickness of a high refractive index part of an organic EL element and the equivalent refractive index of the waveguide mode for different wavelengths in accordance with Example 1.

FIG. 13 is a graph representing a relationship between the thickness of a high refractive index part of an organic EL element and the equivalent refractive index of the waveguide mode for different wavelengths in accordance with Example 2.

FIG. 14 is a graph representing a relationship between the thickness of a high refractive index part of an organic EL element and the equivalent refractive index of the waveguide mode for different wavelengths in accordance with Example 3.

FIG. 15 is a graph representing a relationship between the thickness of a high refractive index part of an organic EL element and the equivalent refractive index of the waveguide mode for different wavelengths in accordance with Example 4.

FIG. 16 is a graph representing a relationship between the thickness of the high refractive index part of the organic EL element and the ratio of a light coupled to each mode for a light having a particular wavelength in accordance with Comparative Example 1.

FIG. 17 is a graph representing a relationship between the thickness of the high refractive index part of the organic EL element and the ratio of a light coupled to each mode for a light having a particular wavelength in accordance with Comparative Example 2.

FIG. 18 is a graph representing a relationship between the thickness of the high refractive index part of the organic EL element and the ratio of a light coupled to each mode for a light having a particular wavelength in accordance with Example 1.

FIG. 19 is a graph representing a relationship between the thickness of the high refractive index part of the organic EL element and the ratio of a light coupled to each mode for a light having a particular wavelength in accordance with Example 2.

FIG. 20 is a graph representing a relationship between the thickness of the high refractive index part of the organic EL element and the ratio of a light coupled to each mode for a light having a particular wavelength in accordance with Example 3.

FIG. 21 is a graph representing a relationship between the thickness of the high refractive index part of the organic EL element and the ratio of a light coupled to each mode for a light having a particular wavelength in accordance with Example 4.

### DESCRIPTION OF EMBODIMENTS

The present inventor obtained a knowledge that a light coupled to the waveguide mode can be reduced drastically by allowing the refractive indices of a pair of transparent electrode layers among various layers constituting an electroluminescent element to be close to the refractive index of a transparent substrate, and reducing the sum total of the film thickness of a part including an electroluminescent layer and the pair of transparent electrode layers having a relatively high refractive index to the thickness which is the same as or close to the thickness as the condition for causing the waveguide mode, or reducing the sum total of the thickness to the thickness which is smaller than the thickness as the condition for causing the waveguide mode, and a light coupled to the plasmon mode can also be reduced drastically by setting the electroluminescent layer and the reflecting layer constituted of a metal film to be sufficiently far apart and filling the space therebetween with a member having a sufficiently low refractive index, and according to those the light emitted from the electroluminescent layer can be extracted with a high efficiency. Then, the present inventor perfected the embodiments of the present invention described herebelow.

Hereinafter, embodiments of the present invention will be described in detail with reference to the drawings. In the following, organic EL elements which are surface light-emitting elements applied with the present invention will be illustrated as first to fourth embodiments, and lighting apparatuses applied with the present invention will be illustrated as fifth and sixth embodiments. It should be noted that the same or common parts have the same reference numerals allotted in the drawings, and description thereof will not be repeated.

### First Embodiment

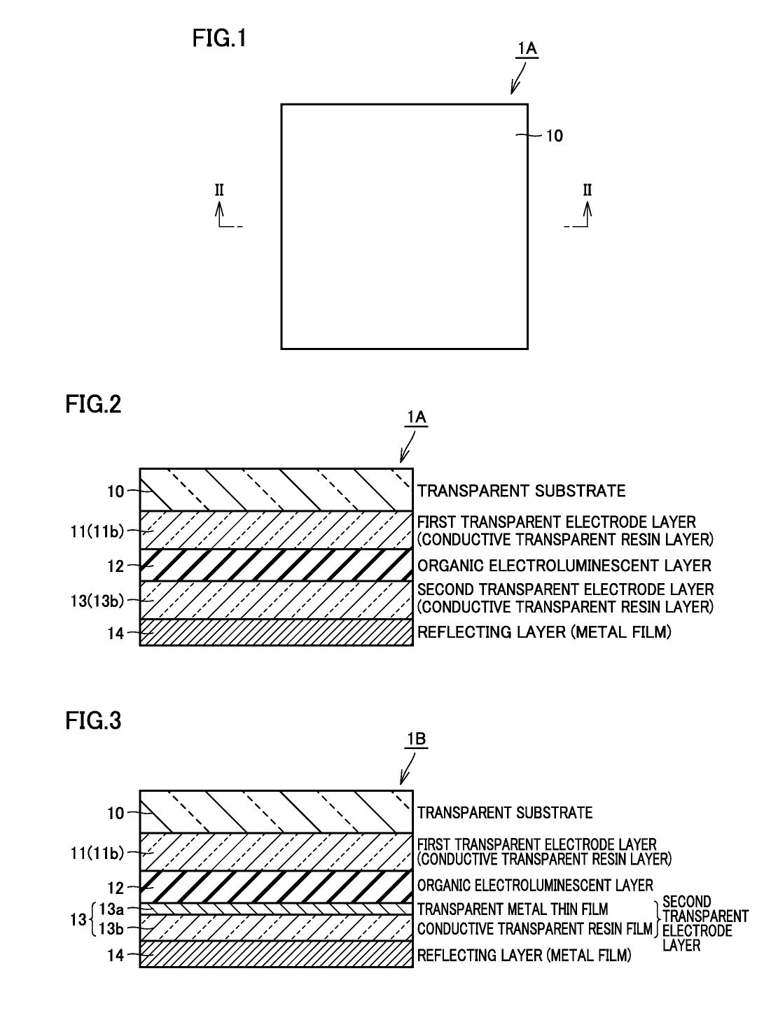

FIG. 1 is a schematic plan view representing an organic EL element in accordance with a first embodiment of the present invention. FIG. 2 is a schematic cross sectional view representing the organic EL element shown in FIG. 1 taken along the II-II line in FIG. 1. Referring to these FIGS. 1 and 2, an organic EL element 1A in accordance with the present embodiment will be described.

As shown in FIGS. 1 and 2, organic EL element 1A in accordance with the present embodiment is a bottom-emission organic EL element which extracts a light through a transparent substrate 10, and its appearance is formed to have a substantially rectangular plate-like or sheet-like shape in a planar view having a predetermined thickness as shown in the drawing. Organic EL element 1A includes a transparent substrate 10, a first transparent electrode layer 11, an organic electroluminescent layer 12, a second transparent electrode layer 13, and a reflecting layer 14. First transparent electrode layer 11 corresponds to an anode, and second transparent electrode layer 13 corresponds to a cathode.

Transparent substrate 10 is a base having the above-described various layers formed on its main surface, and it is constituted of an insulating member which favorably transmits a light in a visible light region. Transparent substrate 10 may be a rigid substrate or a flexible substrate. Transparent substrate 10 is constituted of, for example, a glass plate, a plastic plate, a polymer film, a silicon plate, or a layered plate of those in view of the above-described optical transparency.

First transparent electrode layer 11 is provided on one main surface of transparent substrate 10 and constituted of a film favorably transmitting a light in the visible light region and having a favorable conductivity. More specifically, first transparent electrode layer 11 is constituted of, for example, a conductive transparent resin film 11b having a sufficiently low refractive index.

First transparent electrode layer 11 is provided on transparent substrate 10 by employing, for example, any of a vapor deposition method, a spin-coating method, a cast method, an ink jet method, a printing method, and the like. Particularly, the spin-coating method, the ink jet method, and the printing method can be particularly suitably used since those methods can readily obtain a uniform film and suppress the occurrence of pinholes.

Organic electroluminescent layer 12 is provided on a main surface of first transparent electrode layer 11 on a side opposite to the side on which transparent substrate 10 is located, and it includes a luminescent layer composed of at least fluorescent luminescence compounds or phosphorescence luminescent compounds and is constituted of a layer which favorably transmits a light in the visible light region. Organic electroluminescent layer 12 may have a hole transport layer which is located on a side of first transparent electrode layer 11 closer to an anode side than the luminescent layer, or may have an electron transport layer which is located on a side of second transparent electrode layer 13 closer to a cathode side than the luminescent layer. Moreover, a lithium fluoride film, an inorganic metal salt layer, or the like may be formed at any position in the thickness direction in organic electroluminescent layer 12.

An organic metal complex may be used as the material of organic electroluminescent layer 12 in view of the improvement in the external quantum efficiency, a longer light emission service life, or the like of organic EL element 1A. A metal element associated with the formation of the complex is preferably one kind of metal belonging to the VIII group, IX group, and X group of the periodic table of elements, Al, or Zn. Particularly, the metal element is preferably Ir, Pt, Al, or Zn.

Organic electroluminescent layer 12 is provided on first transparent electrode layer 11 by employing, for example, any of the spin-coating method, the cast method, the ink jet method, the printing method, and the like. Particularly, the spin-coating method, the ink jet method, and the printing method can be suitably used since those methods can readily obtain a uniform film and suppress the occurrence of pinholes.

Second transparent electrode layer 13 is provided on a main surface of organic electroluminescent layer 12 on a side opposite to the side on which first transparent electrode layer 11 is located, and it is constituted of a film which favorably transmits a light in the visible light region and exhibits a favorable conductivity. More specifically, second transparent electrode layer 13 is constituted of, for example, a conductive transparent resin film 13b having a sufficiently low refractive index.

Second transparent electrode layer 13 is provided on organic electroluminescent layer 12 by employing, for example, any of the vapor deposition method, the spin-coating method, the cast method, the ink jet method, the printing method, and the like. Particularly, the spin-coating method, the ink jet method, and the printing method can be suitably used since those methods can readily obtain a uniform film and suppress the occurrence of pinholes.

Reflecting layer 14 is provided on a main surface of second transparent electrode layer 13 on a side opposite to the side on which organic electroluminescent layer 12 is located, and it is constituted of a film which favorably reflects a light in the visible light region. More specifically, reflecting layer 14 is constituted of a metal film made of, for example, Al, Ag, Ni, Ti, Na, Ca, or alloy containing any of those elements. Reflecting layer 14 is provided on second transparent electrode layer 13 by employing, for example, a vapor deposition method, a spattering method, or the like.

Organic EL element 1A according to the present embodiment is configured so that a refractive index ns of transparent substrate 10 is lower than the refractive index of any film included in organic electroluminescent layer 12 (in other words, lower than a refractive index n0 of a film having the lowest refractive index among the films included in organic electroluminescent layer 12) (ns<n0), and so that both a refractive index n1 of first transparent electrode layer 11 and a refractive index n2 of second transparent electrode layer 13 are lower than the refractive index of any film included in organic electroluminescent layer 12 (in other words, lower than refractive index n0 of a film having the lowest refractive index among the films included in organic electroluminescent layer 12) (n1<n0 and n2<n0).

In other words, since the refractive index of the film included in organic electroluminescent layer 12 is generally about 1.7 to 1.9, refractive index ns of transparent substrate 10 is configured to be about 1.5 to 1.7 which is lower than refractive index n0=1.7 of a film having the lower refractive index among the films included in organic electroluminescent layer 12, and a refractive index n1 of first transparent electrode layer 11 constituted of conductive transparent resin film 11b and a refractive index n2 of second transparent electrode layer 13 constituted of conductive transparent resin film 13b are configured to be about 1.5 to 1.7 which is lower than refractive index n0=1.7 of a film having the lowest refractive index among the films included in organic electroluminescent layer 12.

Moreover, it is desirable that refractive index n1 of first transparent electrode layer 11 constituted of conductive transparent resin film 11b and refractive index n2 of second transparent electrode layer 13 constituted of conductive transparent resin film 13b are configured to be refractive indices close to refractive index ns of transparent substrate 10.

Transparent substrate 10 satisfying the conditions described above includes the above-described glass plate, plastic plate, polymer film, silicon plate, or layered plate of those having a refractive index of about 1.5 to 1.7, and a member having a refractive index around 1.5 is favorably used. On the other hand, a specific material of conductive transparent resin films 11b, 13b includes, for example, PEDOT/PSS (a mixture of polyethylenedioxythiophene and polystyrene sulfonic acid) and the like, and its refractive index is generally about 1.5.

Moreover, in organic EL element 1A in accordance with the present embodiment, a high refractive index part included in organic EL element 1A is limited to organic electroluminescent layer 12. When the thickness thereof is d, and the effective refractive index is n, and the peak wavelength of the light emitted from organic electroluminescent layer 12 is λ, the items d, n, and λ, are favorably configured to satisfy the condition of d<λ/(4×n).

When organic EL element 1A emits a white light, the wavelength of the light emitted from organic electroluminescent layer 12 generally matches with the wavelength in the visible light region and is about 400 nm to 800 nm.

In organic EL element 1A in accordance with the present embodiment described above, since both first transparent electrode layer 11 and second transparent electrode layer 13 are constituted of conductive transparent resin films 11b, 13b having sufficiently low refractive indices as described above, the difference in the refractive index between first transparent electrode layer 11 and transparent substrate 10 determining the total reflection condition at the interface between first transparent electrode layer 11 and transparent substrate 10 can be reduced or eliminated, so that the light coupled to the waveguide mode can be reduced.

Moreover, in organic EL element 1A in accordance with the present embodiment, since both first transparent electrode layer 11 and second transparent electrode layer 13 are constituted of conductive transparent resin films 11b, 13b having sufficiently low refractive indices as described above, the high refractive index part included in organic EL element 1A can be limited to organic electroluminescent layer 12, so that the thickness of organic electroluminescent layer 12 as the high refractive index part can be reduced to the thickness which is equal to the thickness of the condition causing the waveguide mode or close to that thickness, or can be reduced to the thickness smaller than the thickness of the condition causing the waveguide mode. Accordingly, the light coupled to the waveguide mode can be reduced drastically or eliminated completely.

Further, in organic EL element 1A in accordance with the present embodiment, since both first transparent electrode layer 11 and second transparent electrode layer 13 are constituted of conductive transparent resin films 11b, 13b having sufficiently low refractive indices as described above, organic electroluminescent layer 12 and reflecting layer 14 constituted of a metal film can be set sufficiently far apart from each other, and a space therebetween can be filled with second transparent electrode layer 13 having a sufficiently low refractive index, the light coupled to the plasmon mode can also be reduced drastically or eliminated completely.

Thus, in organic EL element 1A in accordance with the present embodiment, both the waveguide loss and the plasmon loss can be reduced, and the light emitted from organic electroluminescent layer 12 can be extracted to outside with a high efficiency.

It should be noted that, even when the thickness of organic electroluminescent layer 12 cannot be set smaller than the thickness of the condition causing the waveguide mode, the effective refractive indices of first transparent electrode layer 11 and second transparent electrode layer 13 can be set sufficiently smaller than the case where these first transparent electrode layer 11 and second transparent electrode layer 13 are configured with use of an ITO film or the like. Thus, the refractive index requirement for transparent substrate 10 is loosened, so that transparent substrate 10 having more advantageous material can be used in view of the cost and workability.

It should be noted that although the present embodiment described above illustrates the case where both first transparent electrode layer 11 and second transparent electrode layer 13 are constituted of conductive transparent resin films having the low refractive indices, substantially the same effect can be obtained as long as at least one of those is constituted of the conductive transparent resin film having the low refractive index.

### Second Embodiment

FIG. 3 is a schematic cross sectional view representing an organic EL element in accordance with a second embodiment of the present invention. Referring to FIG. 3, an organic EL element 1B in accordance with the present embodiment will be described.

As shown in FIG. 3, organic EL element 1B in accordance with the present embodiment is different only in the configuration of second transparent electrode layer 13 when it is compared with organic EL element 1A in accordance with the above-described first embodiment. Specifically, in organic EL element 1B, second transparent electrode layer 13 is constituted of a layered film of a transparent metal thin film 13a and a conductive transparent resin film 13b.

Transparent metal thin film 13a is provided on a main surface of organic electroluminescent layer 12 on a side opposite to the side on which first transparent electrode layer 11 is located, and it is constituted of a metal thin film made of, for example, Ag, Al, Au, Cu, or the like. Transparent metal thin film 13a is provided on organic electroluminescent layer 12 by employing, for example, a vapor deposition method, a spattering method, or the like.

The thickness of the metal thin film for transmitting a light can be expressed with use of an imaginary part of the refractive index. When a refractive index n and an extinction coefficient κ are used, a phase change φ and a transmissivity T, which occur when passing through a medium having a thickness d, are provided by the following expressions (1) and (2).

$$\begin{matrix}[ Expression 1 ] & \\ φ = n \frac{2 π}{λ} d & ( 1 ) \\ [ Expression 2 ] & \\ T = exp ( - κ \frac{4 π}{λ} d ) & ( 2 )\end{matrix}$$

Item λ, is the wavelength of a light in vacuum. From the expression (1), a distance Ld at which the light intensity is attenuated to 1/e2 is provided by the following expression (3).

$$\begin{matrix}[ Expression 3 ] & \\ {L}_{d} = \frac{λ}{2 πκ} & ( 3 )\end{matrix}$$

Therefore, it is desirable that transparent metal thin film 13a is thinner than distance Ld provided by the above-described expression (2) to have a sufficient transmittivity.

Conductive transparent resin film 13b is provided on a main surface of transparent metal thin film 13a on a side opposite to the side on which organic electroluminescent layer 12 is located. A material, a film-forming method, and the like of conductive transparent resin film 13b are the same as those in accordance with the above-described first embodiment.

Organic EL element 1B in accordance with the present embodiment is so configured that refractive index ns of transparent substrate 10 is lower than the refractive index of any film included in organic electroluminescent layer 12 (in other words, smaller than refractive index n0 of a film having the lowest refractive index among the films included in organic electroluminescent layer 12) (ns<n0), and that both refractive index n1 of first transparent electrode layer 11 and effective refractive index n2 of second transparent electrode layer 13 constituted of a layered film of transparent metal thin film 13a and conductive transparent resin film 13b are lower than the refractive index of any film included in organic electroluminescent layer 12 (in other words, lower than refractive index n0 of a film having the lowest refractive index among the films included in organic electroluminescent layer 12) (n1<n0 and n2<n0). It should be noted that, since the thickness of transparent metal thin film 13a is sufficiently smaller than the thickness of conductive transparent resin film 13b, effective refractive index n2 of second transparent electrode layer 13 is substantially equal to the refractive index of conductive transparent resin film 13b.

Moreover, it is desirable that effective refractive index n2 of second transparent electrode layer 13 constituted of a layered film of transparent metal thin film 13a and conductive transparent resin film 13b is configured to be the refractive index close to refractive index ns of transparent substrate 10.

Transparent metal thin film 13a satisfying the conditions described above may be the above-described sufficiently thinned metal thin film made of Ag, Al, Au, Cu, or the like.

Moreover, also in organic EL element 1B in accordance with the present embodiment, the high refractive index part included in organic EL element 1B is substantially limited to organic electroluminescent layer 12. When the thickness of the high refractive index part is d, and its effective refractive index is n, and the peak wavelength of light emitted from organic electroluminescent layer 12 is λ, these items d, n, and λ, are favorably configured to satisfy the condition of d<λ/(4×n).

In organic EL element 1B in accordance with the present embodiment described above, since first transparent electrode layer 11 is constituted of conductive transparent resin film 11b having a sufficiently low refractive index, and second transparent electrode layer 13 is constituted of a layered film of transparent metal thin film 13a and conductive transparent resin film 13b having a sufficiently low effective refractive index as described above, the light coupled to the waveguide mode and plasmon mode can be reduced drastically or eliminated completely as with the case of the above-described first embodiment.

Thus, in organic EL element 1B in accordance with the present embodiment, both the waveguide loss and plasmon loss can be reduced, and the light emitted from organic electroluminescent layer 12 can be extracted to outside with a high efficiency.

It should be noted that, in organic EL element 1B in accordance with the present embodiment, since transparent metal thin film 13a is located in contact with organic electroluminescent layer 12, the occurrence of the plasmon loss is concerned. However, when the thickness of transparent metal thin film 13a is configured to be sufficiently small (for example, the thickness is less than or equal to 10 nm), the plasmon loss due to the metal thin film does not occur. Further, since the sufficiently thin thickness of transparent metal thin film 13a also improves the transmittance, the transmittivity of second transparent electrode layer 13 is not lost.

### Third Embodiment

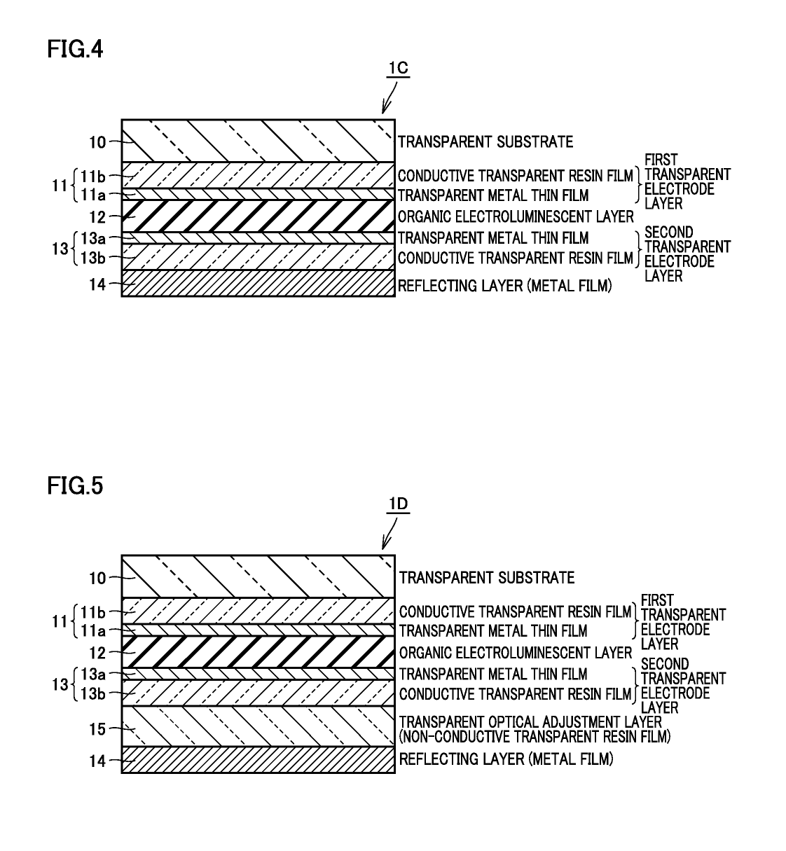

FIG. 4 is a schematic cross sectional view representing an organic EL element in accordance with a third embodiment of the present invention. Referring to FIG. 4, an organic EL element 1C in accordance with the present embodiment will be described.

As shown in FIG. 4, organic EL element 1C in accordance with the present embodiment is different only in the configuration of first transparent electrode layer 11 when it is compared with organic EL element 1B in accordance with the above-described second embodiment. Specifically, in organic EL element 1C, first transparent electrode layer 11 is also constituted of a layered film of transparent metal thin film 11a and conductive transparent resin film 11b as with second transparent electrode layer 13.

Conductive transparent resin film 11b is provided on a main surface of transparent substrate 10 on a side where organic electroluminescent layer 12 is located. A material, a film-forming method, and the like of conductive transparent resin film 11b is the same as those in the above-described first embodiment.

Transparent metal thin film 11a is provided on a main surface of conductive transparent resin film 11b on a side opposite to the side on which transparent substrate 10 is located. The material, film-forming method, film thickness, and the like of transparent metal thin film 11a is the same as those of transparent metal thin film 13a described in the above-described second embodiment.

In organic EL element 1C in accordance with the present embodiment, refractive index ns of transparent substrate 10 is configured to be lower than the refractive index of any film included in organic electroluminescent layer 12 (in other words, lower than refractive index n0 of a film having the lowest refractive index among the films included in organic electroluminescent layer 12) (ns<n0), and both effective refractive index n1 of first transparent electrode layer 11 constituted of a layered film of transparent metal thin film 11a and conductive transparent resin film 11b and effective refractive index n2 of second transparent electrode layer 13 constituted of a layered film of transparent metal thin film 13a and conductive transparent resin film 13b are lower than the refractive index of any film included in organic electroluminescent layer 12 (in other words, lower than refractive index n0 of a film having the lowest refractive index among the films included in organic electroluminescent layer 12) (n1<n0 and n2<n0). It should be noted that, since the thickness of transparent metal thin film 11a is sufficiently smaller than the thickness of conductive transparent resin film 11b, effective refractive index n1 of first transparent electrode layer 11 is substantially equal to the refractive index of conductive transparent resin film 11b.

Moreover, effective refractive index n1 of first transparent electrode layer 11 constituted of a layered film of transparent metal thin film 11a and conductive transparent resin film 11b is desirably configured to be the refractive index close to refractive index ns of transparent substrate 10.

Moreover, also in organic EL element 1C in accordance with the present embodiment, the high refractive index part included in organic EL element 1C is substantially limited to organic electroluminescent layer 12. When the thickness of the high refractive index part is d, and its effective refractive index is n, and the peak wavelength of light emitted from organic electroluminescent layer 12 is λ, these items d, n, and λ, are favorably configured to satisfy the condition of d<λ/(4×n).

In organic EL element 1C in accordance with the present embodiment described above, since first transparent electrode layer 11 is constituted of a layered film of transparent metal thin film 11a and conductive transparent resin film 11b having a sufficiently low effective refractive index, and second transparent electrode layer 13 is constituted of a layered film of transparent metal thin film 13a and conductive transparent resin film 13b having a low effective refractive index as described above, the light coupled to the waveguide mode and plasmon mode can be reduced drastically or eliminated completely as with the case of the above-described first and second embodiments.

Thus, in organic EL element 1C in accordance with the present embodiment, both the waveguide loss and plasmon loss can be reduced, and the light emitted from organic electroluminescent layer 12 can be extracted to outside with a high efficiency.

### Fourth Embodiment

FIG. 5 is a schematic cross sectional view representing an organic EL element in accordance with a fourth embodiment of the present invention. Referring to FIG. 5, an organic EL element 1D in accordance with the present embodiment will be described.

As shown in FIG. 5, organic EL element 1D in accordance with the present embodiment is different only in further including a transparent optical adjustment layer 15 when it is compared with the case of organic EL element 1C in accordance with the above-described third embodiment.

Transparent optical adjustment layer 15 is provided on a main surface of second transparent electrode layer 13 on a side opposite to the side on which organic electroluminescent layer 12 is located, and it is constituted of an insulating layer which favorably transmits the light in the visible light region. More specifically, transparent optical adjustment layer 15 is constituted of, for example, a non-conductive transparent film having a sufficiently low refractive index as represented by an SiOx film.

Transparent optical adjustment layer 15 is provided on second transparent electrode layer 13 by employing any of, for example, a vapor deposition method, a spin-coating method, a cast method, an ink jet method, a printing method, and the like. Particularly, the spin-coating method, ink jet method, and printing method can be favorably used since those methods can readily obtain a uniform film and suppress the occurrence of pinholes.

In organic EL element 1D in accordance with the present embodiment described above, since the high refractive index part included in organic EL element 1D can be substantially limited to organic electroluminescent layer 12, the light coupled to the waveguide mode and plasmon mode can be reduced drastically or eliminated completely as with the case of the above-described third embodiment.

Thus, in organic EL element 1D in accordance with the present embodiment, both the waveguide loss and plasmon loss can be reduced, and the light emitted from organic electroluminescent layer 12 can be extracted to outside with a high efficiency.

Moreover, in organic EL element 1D in accordance with the present embodiment, as compared to organic EL element 1C in accordance with the above-described third embodiment, providing transparent optical adjustment layer 15 having a predetermined thickness allows organic electroluminescent layer 12 and reflecting layer 14 constituted of a metal film to be set far apart from each other and fill a space therebetween with the member having a sufficiently low refractive index. Thus, by employing this configuration, the effect of enabling further reduction of the light coupled to the plasmon mode can be obtained. It should be noted that, in organic EL element 1C in the above-described third embodiment, such a configuration is advantageous in that the light absorption loss is reduced as compared to the case where the thickness of conductive transparent resin film 13b included in second transparent electrode layer 13 is simply increased.

### Fifth Embodiment

FIG. 5 is a schematic view representing a lighting apparatus in accordance with a fifth embodiment of the present invention. Referring to FIG. 5, a lighting apparatus 20A in accordance with the present embodiment will be described.

As shown in FIG. 5, lighting apparatus 20A in accordance with the present embodiment is a room light installed on a ceiling 22 of a room 21, and illuminates inside of room 21. Lighting apparatus 20A includes inside thereof organic EL element 1A in accordance with the above-described first embodiment as a light source. Lighting apparatus 20A irradiates, for example, a white light inside the room.

Lighting apparatus 20A in accordance with the present embodiment can be configured to be thin by including organic EL element 1A as a light source. Moreover, since the extraction efficiency of light irradiated to outside is favorable as compared to the conventional one, a high brightness can be achieved with low power consumption.

It should be noted that, in place of organic EL element 1A, organic EL elements 1B to 1D in accordance with the above-described second through fourth embodiments can be naturally mounted to lighting apparatus 20A as a light source.

### Sixth Embodiment

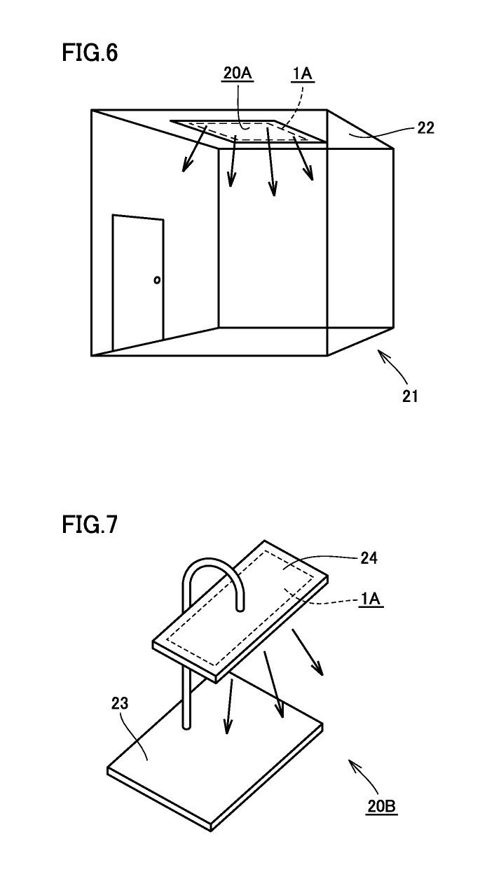

FIG. 6 is a schematic view representing a lighting apparatus in accordance with a sixth embodiment of the present invention. Referring to FIG. 6, a lighting apparatus 20B in accordance with the present embodiment will be described.

As shown in FIG. 6, lighting apparatus 20B in accordance with the present embodiment is, for example, an lighting stand mounted on a desk or the like and used, and mainly illuminates a location near hands. Lighting apparatus 20B has a stand portion 23 and a head portion 24. Organic EL element 1A in accordance with the above-described first embodiment is provided as a light source inside of heat portion 24 among those. Lighting apparatus 20B irradiates, for example, a white light to the location near hands.

Lighting apparatus 20B in accordance with the present embodiment can be configured to be thin by including organic EL element 1A as a light source. Since the extraction efficiency of the light irradiated to outside is more favorable as compared to the conventional one, a high brightness can be achieved with low power consumption.

It should be noted that, in place of organic EL element 1A, organic EL elements 1B to 1D in accordance with the above-described second through fourth embodiments can be naturally mounted as a light source to lighting apparatus 20B.

### EXAMPLES

In the following, organic EL elements 1A to 1D in accordance with the above-described first through fourth embodiments are modeled respectively as Examples 1 through 4, and optical properties of those are analyzed, and a result of reviewing the extent of reduction of the waveguide loss and plasmon loss will be described. It should be noted that, for the comparison, the same analysis was conducted for organic EL elements 100A, 100B in accordance with Comparative Examples 1 and 2 described herebelow.

### Comparative Examples 1 and 2

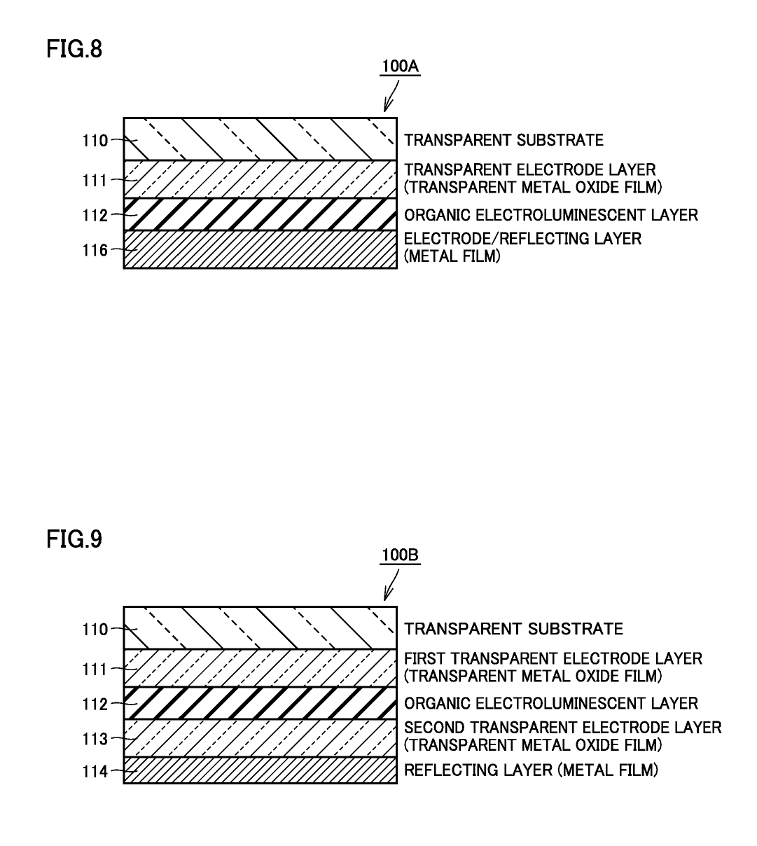

FIG. 8 is a schematic cross sectional view representing the organic EL element in accordance with Comparative Example 1, and FIG. 9 is a schematic cross sectional view representing the organic EL element in accordance with Comparative Example 2.

As shown in FIG. 8, organic EL element 100A in accordance with Comparative Example 1 has a configuration in which a transparent substrate 110, a transparent electrode layer 111, an organic electroluminescent layer 112, and an electrode/reflecting layer 116 are sequentially layered in this order. More specifically, transparent electrode layer 111 is constituted of a transparent metal oxide film, and electrode/reflecting layer 116 is constituted of a metallic film.

As shown in FIG. 9, organic EL element 100B in accordance with Comparative Example 2 has a configuration in which a transparent substrate 110, a first transparent electrode layer 111, an organic electroluminescent layer 112, a second transparent electrode layer 113, and a reflecting layer 114 are sequentially layered in this order. More specifically, first transparent electrode layer 111 and second transparent electrode layer 113 are constituted of transparent metal oxide films, and reflecting layer 114 is constituted of a metal film.

(Reviewed Matters)

For the review described above, the analysis of calculating a relationship between the thickness of the high refractive index part formed in the organic EL element and the equivalent refractive index of the waveguide mode for different wavelengths (it will be referred to as “analysis A”) was conducted, and the analysis of calculating a relationship between the thickness of the high refractive index part and a ratio of light coupled to each mode for a specified wavelength (it will be referred to as “analysis B”) was conducted. It should be noted that the equivalent refractive index of the waveguide mode is the equivalent refractive index sensed by the waveguide mode propagated across both the high refractive index part and the low refractive index part. With the former analysis (analysis A), the amount of the waveguide loss to be reduced can be grasped, and the amount of refractive index of the transparent substrate to be lowered can be lowered. Moreover, with the latter analysis (analysis B), the amount of the waveguide loss and plasmon loss to be reduced can be grasped, and the extent of improvement in the ratio of the light which can be extracted to outside can be grasped.

### Comparative Examples 1, 2 and Examples 1 Through 4

Firstly, before describing the result of review, a specific material, thickness, and the like of each configuration included in Comparative Examples 1, 2 and Examples 1 to 4 as models will be described. It should be noted that, in each model, the thickness of the organic electroluminescent layer is variable.

The organic EL element according to Comparative Example 1 is organic EL element 100A shown in FIG. 8. In the organic EL element according to Comparative Example 1, transparent substrate 110 was constituted of optical glass BK7 (a refractive index of 1.5, and a plate thickness of 0.7 mm), and transparent electrode layer 111 was constituted of an ITO film (a refractive index of 1.8 to 2.2, and a film thickness of 100 nm), and organic electroluminescent layer 112 was constituted of a layered film (a refractive index of 1.7 to 1.9 for each film (a refractive index of 1.8 as a representative value), and a total film thickness of 100 nm) including organic material represented by Alq3 (Tris (8-hydroxyquinolinato) aluminum), and electrode/reflecting layer 116 was constituted of an Al film (a film thickness of 100 nm).

The organic EL element according to Comparative Example 2 is organic EL element 100B shown in FIG. 9. In the organic EL element according to Comparative Example 2, transparent substrate 110 was constituted of optical glass BK7 (a refractive index of 1.5, and a plate thickness of 0.7 mm), and first transparent electrode layer 111 and second transparent electrode layer 113 were constituted of ITO films (a refractive index of 1.8 to 2.2, and a film thickness of 100 nm) respectively, and organic electroluminescent layer 112 was constituted of a layered film (a refractive index of 1.7 to 1.9 for each film (a refractive index of 1.8 as a representative value), and a total film thickness of 100 nm) including organic material represented by Alq3, and reflecting layer 114 was constituted of an Al film (a film thickness of 100 nm).

The organic EL element according to Example 1 has the same configuration as organic EL element 1A in accordance with the above-described first embodiment. In the organic EL element according to Example 1, transparent substrate 10 was constituted of optical glass BK7 (a refractive index of 1.5, and a plate thickness of 0.7 mm), and conductive transparent resin film 11b as first transparent electrode layer 11 and conductive transparent resin film 13b as second transparent electrode layer 13 were constituted of PEDOT/PSS films (a refractive index of 1.5, and a film thickness of 100 nm) respectively, and organic electroluminescent layer 12 was constituted of a layered film (a refractive index of 1.7 to 1.9 for each film (a refractive index of 1.8 as a representative value), and a total film thickness of 100 nm) including organic material represented by Alq3, and reflecting layer 14 was constituted of an Al film (film thickness of 100 nm).

The organic EL element according to Example 2 has the same configuration as organic EL element 1B in accordance with the above-described second embodiment. In the organic EL element according to Example 2, transparent substrate 10 was constituted of optical glass BK7 (a refractive index of 1.5, and a plate thickness of 0.7 mm), and conductive transparent resin film 11b as first transparent electrode layer 11 was constituted of a PEDOT/PSS film (a refractive index of 1.5, and a film thickness of 100 nm), and transparent metal thin film 13a as second transparent electrode layer 13 was constituted of an Ag film (a film thickness of 6 nm), and conductive transparent resin film 13b as second transparent electrode layer 13 was constituted of a PEDOT/PSS film (a refractive index of 1.5, and a film thickness of 100 nm), and organic electroluminescent layer 12 was constituted of a layered film (a refractive index of 1.7 to 1.9 for each film (a refractive index of 1.8 as a representative value), and a total film thickness of 100 nm) including organic material represented by Alq3, and reflecting layer 14 was constituted of an Al film (film thickness of 100 nm).

The organic EL element according to Example 3 has the same configuration as organic EL element 1C in accordance with the above-described third embodiment. In the organic EL element according to Example 3, transparent substrate 10 was constituted of optical glass BK7 (a refractive index of 1.5, and a plate thickness of 0.7 mm), and transparent metal thin film 11a as first transparent electrode layer 11 and transparent metal thin film 13a as second transparent electrode layer 13 were constituted of Ag films (a film thickness of 6 nm) respectively, and conductive transparent resin film 11b as first transparent electrode layer 11 and conductive transparent resin film 13b as second transparent electrode layer 13 were constituted of PEDOT/PSS films (a refractive index of 1.5, and a film thickness of 100 nm) respectively, and organic electroluminescent layer 12 was constituted of a layered film (a refractive index of 1.7 to 1.9 for each film (a refractive index of 1.8 as a representative value), and a total film thickness of 100 nm) including organic material represented by Alq3, and reflecting layer 14 was constituted of an Al film (a film thickness of 100 nm).

The organic EL element according to Example 4 has the same configuration as organic EL element 1D in accordance with the above-described fourth embodiment. In the organic EL element according to Example 4, transparent substrate 10 was constituted of optical glass BK7 (a refractive index of 1.5, and a plate thickness of 0.7 mm), and transparent metal thin film 11a as first transparent electrode layer 11 and transparent metal thin film 13a as second transparent electrode layer 13 were constituted of Ag films (a film thickness of 6 nm) respectively, and conductive transparent resin film 11b as first transparent electrode layer 11 and conductive transparent resin film 13b as second transparent electrode layer 13 were constituted of PEDOT/PSS films (a refractive index of 1.5, and a film thickness of 100 nm) respectively, and organic electroluminescent layer 12 was constituted of a layered film (a refractive index of 1.7 to 1.9 for each film (a refractive index of 1.8 as a representative value), and a total film thickness of 100 nm) including organic material represented by Alq3, and transparent optical adjustment layer 15 was constituted of an SiOx film (a refractive index of 1.5, and a film thickness of 100 nm), and reflecting layer 14 was constituted of an Al film (a film thickness of 100 nm).

(Result of Review Based on Analysis A)

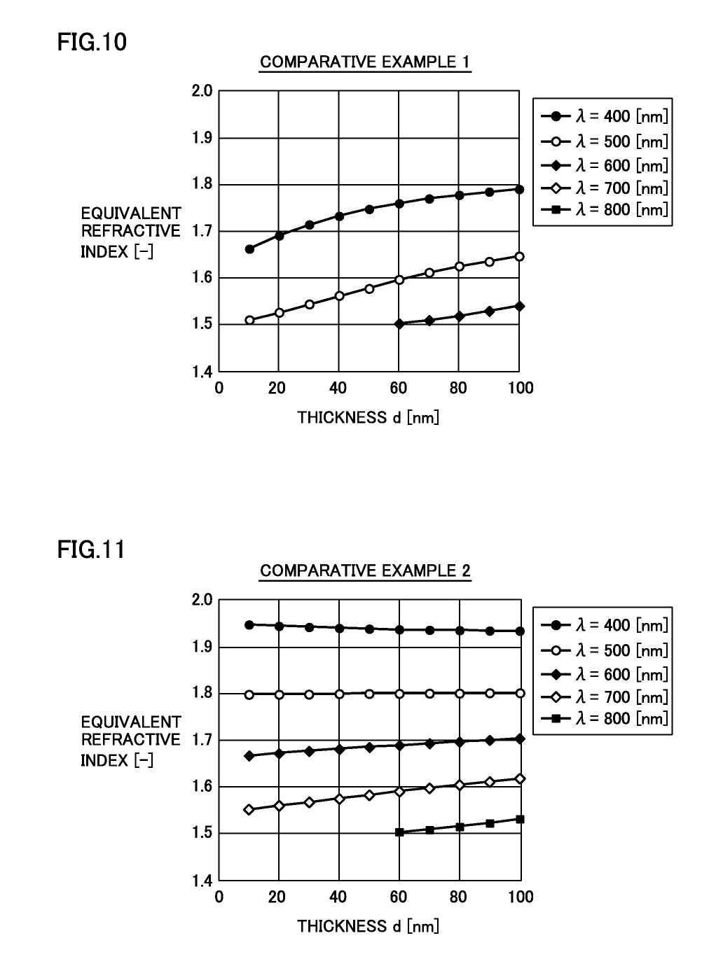

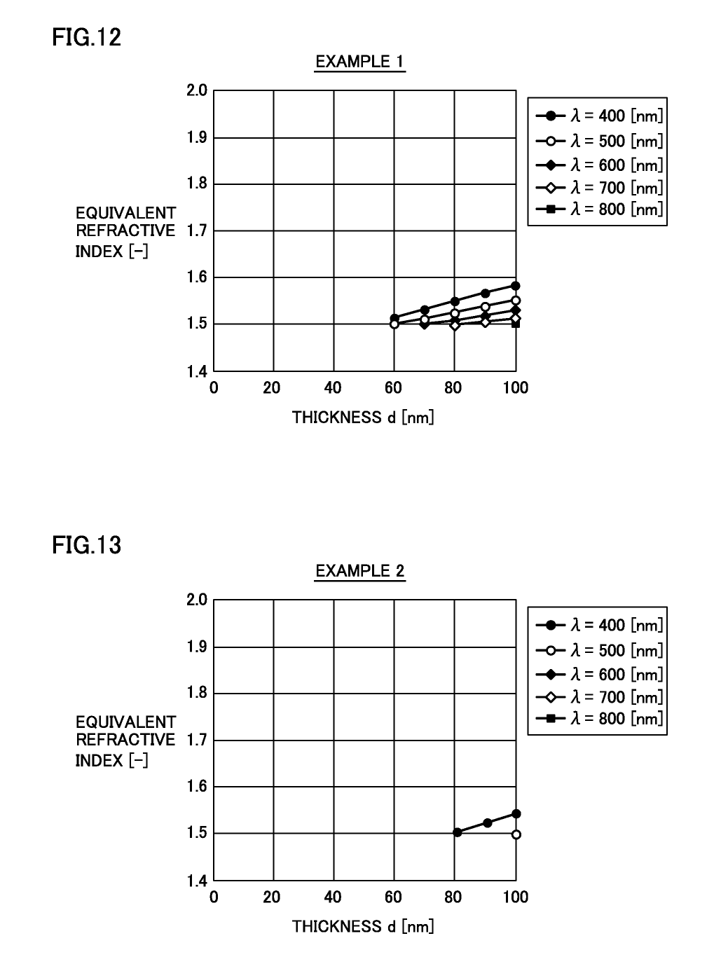

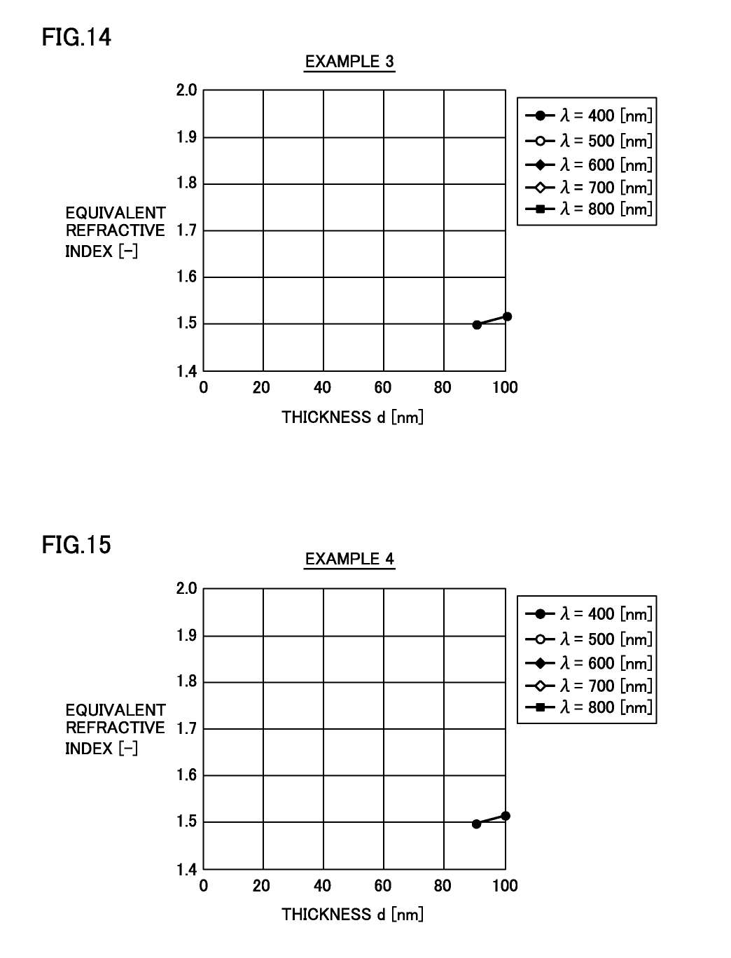

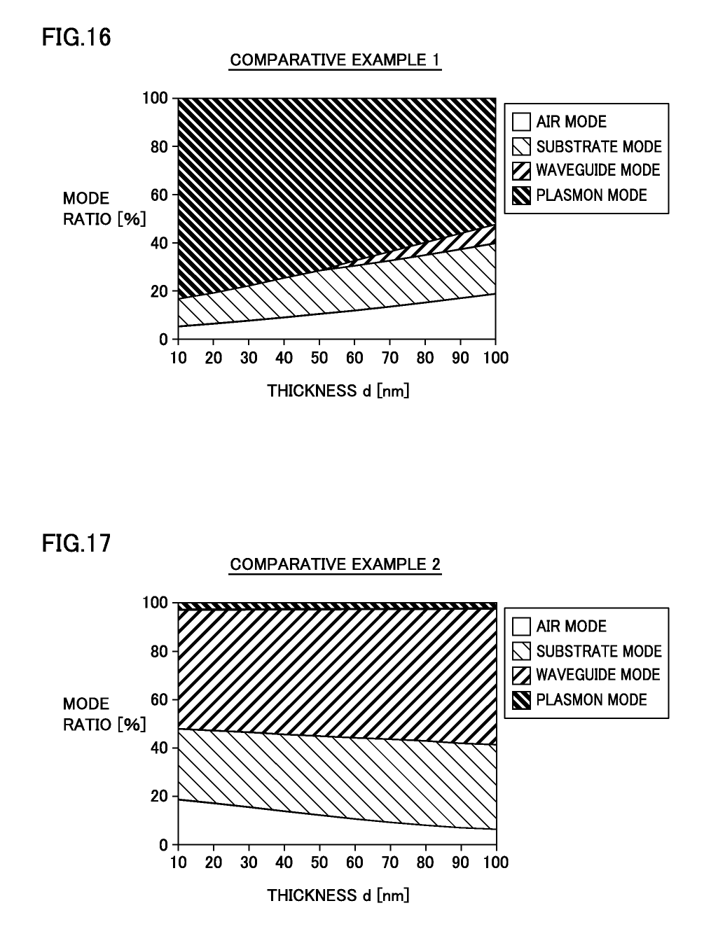

FIGS. 10 and 11 are graphs representing a relationship between the thickness of the high refractive index parts of the organic EL elements and the equivalent refractive index of the waveguide mode for different wavelengths according to Comparative Examples 1 and 2, and FIGS. 12 through 15 are graphs representing the thickness of the high refractive index parts of the organic EL elements and the equivalent refractive index of the waveguide mode for different wavelengths according to Examples 1 through 4.

As shown in FIG. 10, in the organic EL element according to Comparative Example 1, since the ITO film as the transparent electrode layer is included in addition to the organic electroluminescent layer, and these correspond to the high refractive index part, the effective thickness of the high refractive index part takes a value obtained by adding 100 nm as a thickness of the ITO film to thickness d denoted in the horizontal axis of FIG. 10. Therefore, the equivalent refractive index in the waveguide mode particularly with respect to the light having a short wavelength is high, and it can be found that, in order to improve the efficiency of the light extracted to outside, a problem arises in which a transparent substrate having a high refractive index, being disadvantageous in view of cost and workability, is required as a transparent substrate.

Moreover, as shown in FIG. 11, in the organic EL element according to Comparative Example 2, an ITO film as the first transparent electrode layer and an ITO film as the second transparent electrode layer are included in addition to the organic electroluminescent layer, and these correspond to the high refractive index part, the effective thickness of the high refractive index part takes a value obtained by adding 200 nm as a sum total of the thicknesses of the ITO films to thickness d denoted in the horizontal axis of FIG. 11. Therefore, as with the case of Comparative Example 1, the equivalent refractive index in the waveguide mode particularly with respect to the light having a short wavelength is high, and it can be found that, in order to improve the efficiency of the light extracted to outside, a problem arises in which a transparent substrate having a high refractive index, being disadvantageous in view of cost and workability, is required as a transparent substrate.

On the other hand, as shown in FIGS. 12 through 15, since the high refractive index part is limited to the organic electroluminescent layer in the organic EL elements according to Examples 1 through 4, the thickness of the high refractive index part matches with thickness d denoted by the horizontal axis of FIG. 11. Therefore, as can be understood from FIGS. 12 through 15, the light having a long wavelength is not coupled to the waveguide mode in the thickness range of 50 nm to 100 nm. Consequently, the equivalent refractive index of the waveguide mode is eliminated. Further, the equivalent refractive index with respect to the light having a short wavelength is also lowered to about 1.5 to 1.6, and it can be found that the transparent substrate having a relatively low refractive index can be used which is advantageous in view of cost and workability.

(Result of Review Based on Analysis B)

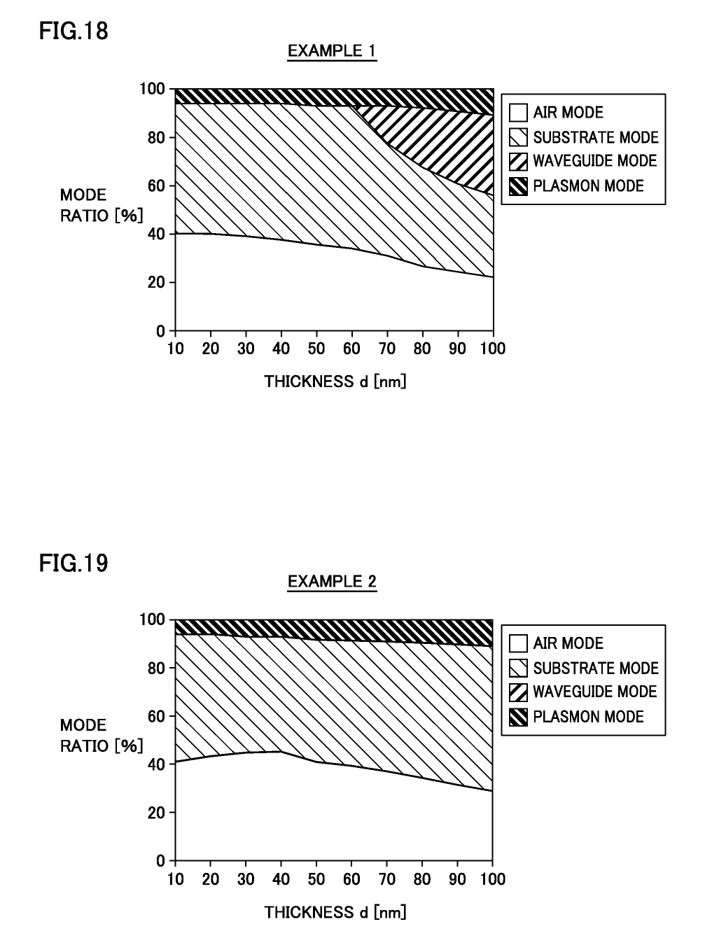

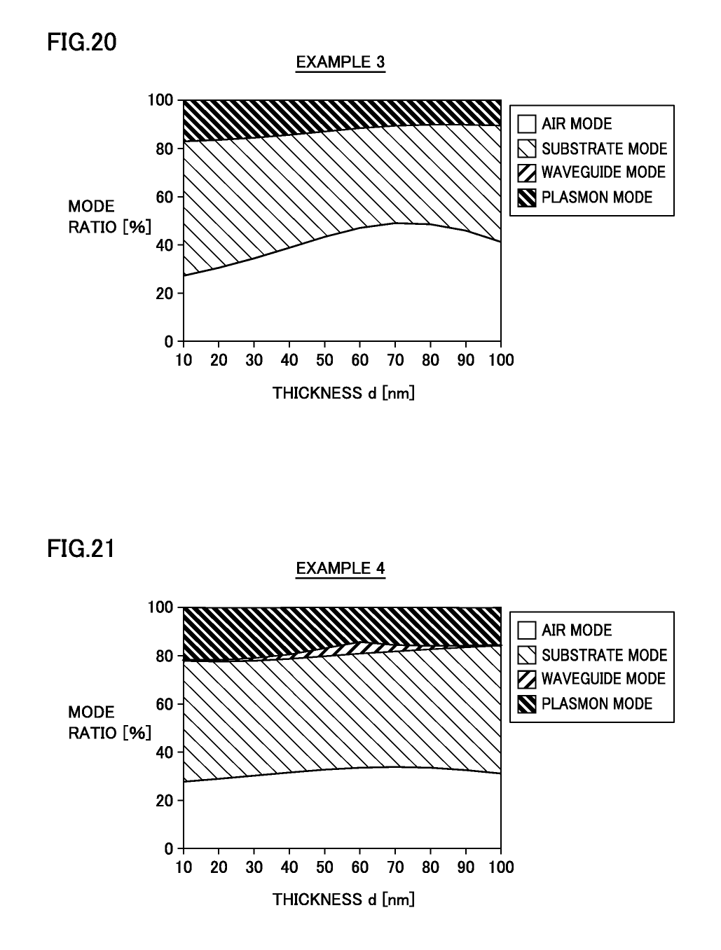

FIGS. 16 and 17 are graphs representing a relationship between the thicknesses of the high refractive index parts of the organic EL elements and ratios of light coupled to each mode for the light having a specific wavelength according to Comparative Examples 1 and 2, and FIGS. 18 through 21 are graphs representing a relationship between the thicknesses of the high refractive index parts of the organic EL elements and the ratios of light coupled to each mode for the light having a specific wavelength according to Examples 1 through 4. The specific wavelength is 600 nm which is a representative wavelength of the visible light. It should be noted that the air mode presented in the drawings is the mode which can extract a light to outside of the organic EL element.

As shown in FIG. 16, in the organic EL element according to Comparative Example 1, the effect of removing a considerable extent of the guided mode is exhibited. However, since the metal film as the electrode/reflecting layer is arranged in contact with the organic electroluminescent layer, the plasmon mode is dominant. Therefore, since the plasmon loss becomes very large, it can be found that the light emitted from the organic electroluminescent layer cannot be extracted to outside with a high efficiency.

Further, as shown in FIG. 17, in the organic EL element according to Comparative Example 2, since the presence of the second transparent electrode layer can secure a distance between the organic electroluminescent layer and the metal film, the effect of removing a considerable extent of the plasmon mode is exhibited. However, since the refractive index of the second transparent electrode layer is high, the waveguide mode is dominant. Therefore, since the waveguide loss becomes very large, it can be found that the light emitted from the organic electroluminescent layer cannot be extracted to outside with a high efficiency. It should be noted that, in order to replace the light coupled to the waveguide mode with the light coupled to the substrate mode, it would be necessary to raise the refractive index of the transparent substrate considerably, and it may be disadvantageous in view of the cost and workability.

On the other hand, as shown in FIG. 18, in the organic EL element according to Example 1, since the first transparent electrode layer and second transparent electrode layer are non-conductive transparent resin films, a sufficiently low refractive index is provided, and the distance between the organic electroluminescent layer and the reflecting layer as the metal film can be sufficiently secured, so that the waveguide mode and plasmon mode are reduced drastically, and along with this the substrate mode and air mode are increased drastically. Particularly, setting thickness d of the organic electroluminescent layer as the high refractive index layer to be less than or equal to 50 nm, the waveguide mode could be removed completely. Thus, it can be found that the waveguide loss and the plasmon loss can be reduced drastically, and the light emitted from the organic electroluminescent layer can be extracted to outside with a high efficiency.

The plasmon mode is slightly increased as compared to the organic EL element according to the above-described Comparative Example 2. It is considered to be caused by that, as the refractive index between the organic electroluminescent layer and the reflecting layer being lower, the optical distance therebetween is slightly closer.

However, it can be found that the organic EL element according to Example 1 is more advantageous than the organic EL element according to Comparative Example 2 in that the waveguide mode can be reduced drastically. Moreover, also in the region having thickness d of the organic electroluminescent layer greater than or equal to 50 nm, as can be understood from FIG. 12, since the light coupled to the waveguide mode can be replaced with the light coupled to the substrate mode with use of the transparent substrate having a refractive index of about 1.6, it can be found that it is advantageous in reducing the waveguide loss drastically.

Moreover, as shown in FIGS. 19 through 21, in the organic EL elements according to Examples 2 through 4, the waveguide mode is completely or almost completely removed. Accordingly, the substrate mode and air mode are increased drastically. Thus, it can be found that the waveguide loss and plasmon loss can be reduced drastically, and the light emitted from the organic electroluminescent layer can be extracted to outside with a high efficiency.

Based on the result of review described above, it could be confirmed that organic EL elements 1A to 1D according to the above-described first through fourth embodiments can provide the effect described in the above-described first through fourth embodiments.

It should be noted that, although providing organic EL elements 1A to 1D according to the above-described first through fourth embodiments can reduce the light coupled to the waveguide mode and plasmon mode, the light coupled to the substrate mode among those modes is the light confined in the transparent substrate, and the light becomes the substrate loss unless some measure is taken. However, as to the substrate mode, since a part of it can be extracted to outside with a multipath reflection with the reflecting layer, for example, by attaching an optical sheet, which is referred to as a light extraction sheet, to an interface with the air of the transparent substrate, or by providing recessed and protruded shapes on the interface, the light can be extracted to outside with higher efficiency by employing these configurations.

In the above-described first through sixth embodiments of the present invention, the case of applying the present invention to the organic EL element including the organic electroluminescent layer and the illumination including the same wad described. However, the scope of the present invention is not limited to this, and the present invention can be naturally applied to the inorganic EL element including the inorganic electroluminescent layer and the lighting apparatus including the same.

Moreover, the room light and the lighting stand were described as examples of the lighting apparatus in the above-described fifth and sixth embodiment of the present invention. However, the scope of the present invention is not limited to this. The present invention can be naturally applied to various devices including an electroluminescent element as a light source (for example, a display or display device, a lighting display signboard or advertisement, an outdoor light, or the like).

Moreover, the characterizing configurations illustrated in the above-described first through sixth embodiments of the present invention can be naturally combined with each other within the range of not departing from the spirit of the present invention.

As described above, the above-described embodiments disclosed herein are examples in all aspects and not limitation. The technical scope of the present invention is defined by the claims and include the meaning equivalent to the recitation of claims and all modifications within the scope.

### REFERENCE SIGNS LIST

1A-1D organic EL element; 10 transparent substrate; 11 first transparent electrode layer; 11a transparent metal thin film; 11b conductive transparent resin film; 12 organic electroluminescent layer; 13 second transparent electrode layer; 13 transparent metal thin film; 13b conductive transparent resin film; 14 reflecting layer; 15 transparent optical adjustment layer; 20A, 20B lighting apparatus; 21 room; 22 ceiling; 23 stand portion; 24 head portion.

1. An electroluminescent element comprising:
a transparent substrate;
a first transparent electrode layer provided on one main surface of the transparent substrate;
an electroluminescent layer provided on a main surface of the first transparent electrode layer on a side opposite to a side on which the transparent substrate is located;
a second transparent electrode layer provided on a main surface of the electroluminescent layer on a side opposite to a side on which the first transparent electrode layer is located; and
a reflective layer constituted of a metal film and provided on a side opposite to a side on which the electroluminescent layer is located when viewed from the second transparent electrode layer,
an effective refractive index of the transparent substrate, an effective refractive index of the first transparent electrode layer, and an effective refractive index of all of layers between the electroluminescent layer and the reflecting layer being lower than a refractive index of any film included in the electroluminescent layer.

2. The electroluminescent element according to claim 1, wherein at least one of the first transparent electrode layer and the second transparent electrode layer is constituted of a conductive transparent resin film.

3. The electroluminescent element according to claim 1, wherein at least one of the first transparent electrode layer and the second transparent electrode layer is constituted of a layered film including a transparent metal thin film and a conductive transparent resin film.

4. The electroluminescent element according to claim 1, wherein when a thickness of the electroluminescent layer is d, and an effective refractive index of the electroluminescent layer is n, and a peak wavelength of a light emitted from the electroluminescent layer is λ, these items d, n, and λ satisfy the condition of d<λ/(4×n).

5. The electroluminescent element according to claim 1, further comprising:
a transparent optical adjustment layer provided between the second transparent electrode layer and the reflecting layer, wherein
an effective refractive index of the transparent optical adjustment layer is lower than a refractive index of any film included in the electroluminescent layer.

6. The electroluminescent element according to claim 1, wherein the electroluminescent layer is an organic electroluminescent layer.

7. A lighting apparatus comprising the electroluminescent element according to claim 1.

8. The electroluminescent element according to claim 3, wherein the second transparent electrode layer is constituted of a layered film including a transparent metal thin film and a conductive transparent resin film.

9. The electroluminescent element according to claim 3, wherein the transparent metal thin film is located on a side closer to the electroluminescent layer than the conductive transparent resin film.

10. The electroluminescent element according to claim 8, wherein the transparent metal thin film is located on a side closer to the electroluminescent layer than the conductive transparent resin film.

11. The electroluminescent element according to claim 3, wherein the first transparent electrode layer and the second transparent electrode layer are constituted of layered films respectively including a transparent metal thin film and a conductive transparent resin film.

12. The electroluminescent element according to claim 11, wherein the transparent metal thin film is located on a side closer to the electroluminescent layer than the conductive transparent resin film.
